(19) United States
(12) Patent Application Publication
(10) Pub. No.: US 2022/0408589 A1
(43) Pub. Date: Dec. 22, 2022

(54) LIQUID-COOLING HEAT SINK

(71) Applicants: INVENTEC (PUDONG) TECHNOLOGY CORPORATION, Shanghai (CN); INVENTEC CORPORATION, Taipei City (TW)

(72) Inventors: Yidong JI, Shanghai (CN); Pinyi XIANG, Shanghai (CN); Jiangjun WU, Shanghai (CN); Xuefeng CHEN, Shanghai (CN)

(21) Appl. No.: 17/467,739

(22) Filed: Sep. 7, 2021

(30) Foreign Application Priority Data
Jun. 16, 2021 (CN) 202110668292.6

(51) Int. Cl. H05K 7/20; F28F 3/12

(52) U.S. Cl. CPC H05K 7/2039; F28F 3/12; H05K 7/20218; F28F 2250/102

(57) ABSTRACT

A liquid-cooling heat sink is disclosed which includes a substrate, a cover and a separator. The substrate includes a plate, a set of first heat sinking fins and a set of second heat sinking fins. The cover has water inlet and outlet ports. The cover and the plate together delimit a heat exchange chamber in which both the set of first heat sinking fins and the set of second heat sinking fins are confined. The separator is disposed between the set of first heat sinking fins and the set of second heat sinking fins to divide the heat exchange chamber into a water inlet compartment and a water outlet compartment. The water inlet compartment and water outlet compartment are in communication with the water inlet and outlet ports respectively. The liquid-cooling heat sink has not only enhanced overall structural strength but also improved heat exchange efficiency with a coolant fluid.

### CROSS-REFERENCES TO RELATED APPLICATION

This application claims the priority of Chinese patent application number 202110668292.6, filed on Jun. 16, 2021, the entire contents of which are incorporated herein by reference.

### TECHNICAL FIELD

The present invention relates to a heat sink and, in particular, to a liquid-cooling heat sink.

### BACKGROUND

Arranged on the motherboard of a computer system, the central processing unit (CPU), North Bridge chip, South Bridge chip and graphics processing unit (GPU) are all integrated circuit (IC) chips that are identified as the most significant heat sources during operation of the system. In order to quickly remove the heat generated by such IC chips on the motherboard during high-speed operation, a water-cooling heat sink system can be used, which has cold plates brought into direct contact with backsides of the respective IC chips. A coolant liquid is circulated through the cold plates to carry away unwanted heat to a water-cooling radiator.

However, with technology ever developing and advancing, increasing heat is generated from operation of modern IC chips, making the capabilities of existing water-cooling heat sink system unable to meet the heat sinking demand of the latest IC chips anymore. Therefore, there is a need to design a water-cooling heat sink system with improved heat sinking capabilities.

### SUMMARY OF THE INVENTION

It is an objective of the present invention to provide a liquid-cooling heat sink capable imparting improved heat sinking capabilities to a water-cooling heat sink system.

In embodiments of the present invention, there is provided a liquid-cooling heat sink including a substrate, a cover and a separator. The substrate includes a plate, a set of first heat sinking fins and a set of second heat sinking fins. The set of first heat sinking fins and the set of second heat sinking fins project from the same side of the plate. The cover has a water inlet port and a water outlet port, and is superimposed on the plate. The cover and the plate together delimit a heat exchange chamber in which both the set of first heat sinking fins and the set of second heat sinking fins are confined. The separator is disposed between the set of first heat sinking fins and the set of second heat sinking fins so as to divide the heat exchange chamber into a water inlet compartment and a water outlet compartment. The water inlet compartment is in communication with the water inlet port, and the water outlet compartment is in communication with the water outlet port. The set of first heat sinking fins is housed in the water inlet compartment, and the set of second heat sinking fins is housed in the water outlet compartment.

In this liquid-cooling heat sink, blocked by the separator, a coolant fluid converges and flows to the outside through the water outlet port, after passing through the first and second heat sinking fins. Therefore, arranging the separator between the first and second heat sinking fins not only strengthens the overall structural strength of the liquid-cooling heat sink but also alters the flow path of the coolant fluid, and thus allows an expanded heat exchange area between the coolant fluid and the liquid-cooling heat sink, resulting in more efficient heat exchange between the coolant fluid and the liquid-cooling heat sink and an additionally reduced temperature of a heat source.

Both the above summary of the present invention and the following detailed description of embodiments thereof are merely exemplary of the principles of the invention and are intended to provide a further explanation of the scope thereof.

### BRIEF DESCRIPTION OF THE DRAWINGS

FIG. 1 is a schematic stereoscopic view of a liquid-cooling heat sink according to an embodiment of the present invention.

FIG. 2 is a schematic exploded view of the liquid-cooling heat sink of FIG. 1.

FIG. 3 is a diagram schematically illustrating the flow of a fluid in the liquid-cooling heat sink of FIG. 1.

In these figures, 10-liquid-cooling heat sink; 100-substrate; 110-plate; 120-set of first heat sinking fins; 121, 122-subset of first heat sinking fins; 130-set of second heat sinking fins; 131, 132-subset of second heat sinking fins; 200-cover; 210-water inlet port; 220-water outlet port; 300-separator; 400-fixation member; 410-first assembly hole; 420-second assembly hole; 500-fastener; 510-water inlet faucet; 520-water outlet faucet; S-heat exchange chamber; S1-water inlet compartment; S2-water outlet compartment; Ci-water inlet passage; Co-water outlet passage; T1-first communication channel; T2-second communication channel; G-gap; A, B1, B2, C1, C2, D1, D2, E-direction.

### DETAILED DESCRIPTION

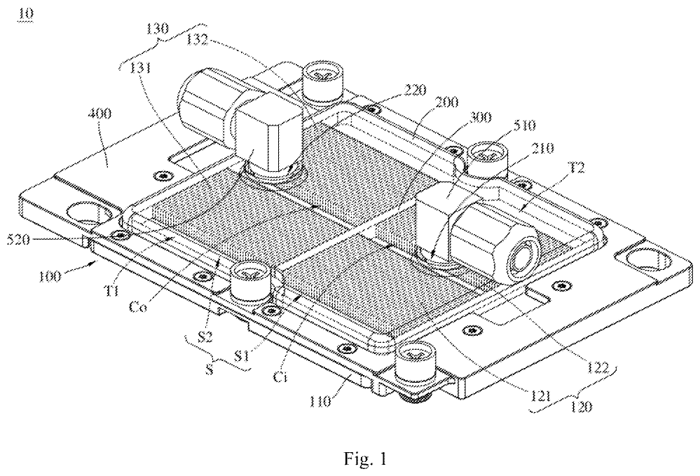

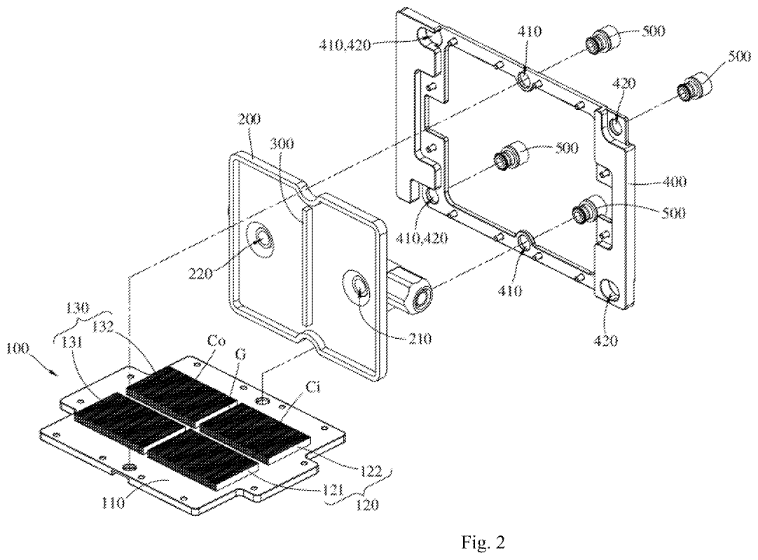

Reference is now made to FIG. 1, a schematic stereoscopic view of a liquid-cooling heat sink according to an embodiment of the present invention, and to FIG. 2, a schematic exploded view of the liquid-cooling heat sink of FIG. 1.

The liquid-cooling heat sink 10 according to this embodiment is, for example, brought into thermal contact with a heat source (not shown) such as a central processing unit (CPU) or an image processor. The liquid-cooling heat sink 10 includes a substrate 100, a cover 200 and a separator 300.

The substrate 100 is made of, for example, a thermally conductive material such as a metal, and includes a plate 110, a set of first heat sinking fins 120 and a set of second heat sinking fins 130. The plate 110 is configured for thermal contact with the heat source. The set of first heat sinking fins 120 and the set of second heat sinking fins 130 both project from the same side of the plate 110 and are spaced apart by a gap G. The cover 200 has a water inlet port 210 and a water outlet port 220. The cover 200 is superimposed on the plate 110 so that the cover 200 and the plate 110 together delimit a heat exchange chamber S in which the set of first heat sinking fins 120 and the set of second heat sinking fins 130 are both confined. The separator 300 is disposed between the set of first heat sinking fins 120 and the set of second heat sinking fins 130 so as to divide the heat exchange chamber S into a water inlet compartment S1 and a water outlet compartment S2. The water inlet port 210 communicates with the water inlet compartment S1, and the water outlet port 220 communicates with the water outlet compartment S2. The set of first heat sinking fins 120 is housed in the water inlet compartment S1, and the set of second heat sinking fins 130 is housed in the water outlet compartment S2.

The set of first heat sinking fins 120, the set of second heat sinking fins 130 and the separator 300 delimit one side thereof a first communication channel T1 together with the cover 200. The first communication channel T1 communicatively connects the water inlet compartment S1 to the water outlet compartment S2. The set of first heat sinking fins 120, the set of second heat sinking fins 130 and the separator 300 further delimit on the other side thereof a second communication channel T2 together with the cover 200. The second communication channel T2 communicatively connects the water inlet compartment S1 to the water outlet compartment S2.

In this and other embodiments, the set of first heat sinking fins 120 includes two subsets of first heat sinking fins 121, 122, which are spaced apart from each other and define a water inlet passage Ci between the two subsets of first heat sinking fins 121, 122. The first communication channel T1 communicatively connects the water inlet passage Ci to the water outlet compartment S2. The set of second heat sinking fins 130 includes two subsets of second heat sinking fins131, 132, which are spaced apart from each other and define a water outlet passage Co between the two subsets of second heat sinking fins131, 132. The first communication channel T1 communicatively connects the water inlet passage Ci to the water outlet passage Co.

In this and other embodiments, the set of first heat sinking fins 120 and the set of second heat sinking fins 130 are formed by skiving in order to result in an increased density of the first and second heat sinking fins 120, 130 and thus improved heat sinking capabilities of the liquid-cooling heat sink 10.

In this and other embodiments, the separator 300 is integrated with the cover 200 on one side and is engaged with the plate 110 on the other side in order to impart improved structural strength to the liquid-cooling heat sink 10. However, the separator 300 is not limited to being so arranged because in other embodiments, it may also be engaged on both sides respectively with the plate 110 and the cover 200. Alternatively, the separator 300 may also be coupled to only the cover 200 but not the plate 110.

In this and other embodiments, the liquid-cooling heat sink 10 may further include a fixation member 400 assembled with the plate 110 of the substrate 100. The fixation member 400 may include a plurality of assembly features having a plurality of first assembly holes 410 and a plurality of second assembly holes 420. The plurality of first assembly holes 410 may at least partially differ from the plurality of second assembly holes 420 in terms of position and configured for assembly with two different objects. The assembly may be with a platform associated with an Intel or AMD CPU.

In this and other embodiments, the liquid-cooling heat sink 10 may further include a plurality of fasteners 500 such as screws. Depending on the object to be assembled with, the fasteners 500 may be inserted through either the first assembly holes 410 or the second assembly holes 420. As an example, if the fixation member 400 is to be assembled with a platform associated with an Intel CPU, then the fasteners 500 may be inserted through the first assembly holes 410. If the fixation member 400 is to be assembled with a platform associated with an AMD CPU, then the fasteners 500 may be inserted through the second assembly holes 420.

In this and other embodiments, the liquid-cooling heat sink 10 may further include a water inlet faucet 510 and a water outlet faucet 520, which are arranged at the water inlet port 210 and the water outlet port 220 of the cover 200, respectively, and configured to connect pipes.

In this embodiment, the water inlet compartment S1 and the water outlet compartment S2 are communicatively connected by the first communication channel T1 and the second communication channel T2, respectively. However, the present invention is not so limited. In alternative embodiments, both the water inlet and outlet compartments may be communicatively connected by only the first or second communication channel.

While the set of first heat sinking fins 120 and the set of second heat sinking fins 130 have been described as being formed by skiving, the present invention is not so limited because in alternative embodiments, they may also be formed by aluminum extrusion.

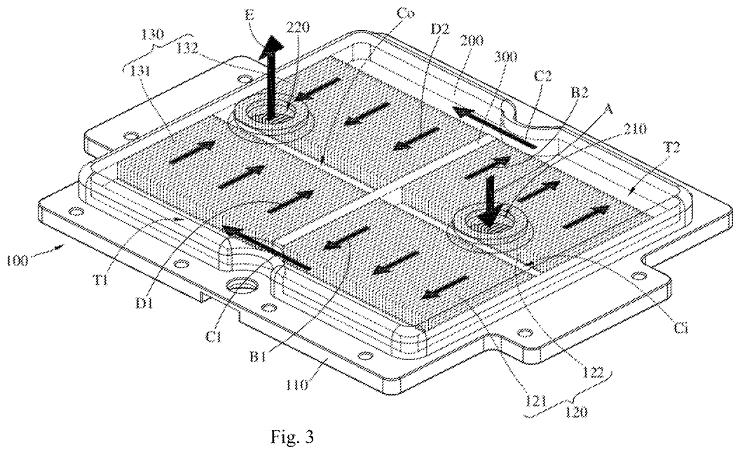

Reference is now made to FIG. 3, a diagram schematically illustrating the flow of a fluid in the liquid-cooling heat sink.

At first, the coolant fluid flows in direction A through the water inlet port 210 of the cover 200 into the water inlet passage Ci in the water inlet compartment S1. It then follows directions B1, B2 to flow through gaps between the two subsets 121, 122 of first heat sinking fins 120 into sections of the first and second communication channels T1, T2 beside the water inlet compartment S1. Thereafter, it follows directions C1, C2 to flow from the sections of the first and second communication channels T1, T2 beside the water inlet compartment S1 into sections of the first and second communication channels T1, T2 beside the water outlet compartment S2. Subsequently, it follows directions D1, D2 to flow through gaps between the two subsets 131, 132 of second heat sinking fins 130 into the water outlet passage Co in the water outlet compartment S2. Afterward, it follows direction E to flow from the water outlet compartment S2 through the water outlet port 220 of the cover 200 to the outside.

Blocked by the separator 300, the coolant fluid converges and flows to the outside through the water outlet port 220, after passing through the first and second heat sinking fins 120, 130. Therefore, arranging the separator 300 between the first and second heat sinking fins 120, 130 not only strengthens the overall structural strength of the liquid-cooling heat sink 10 but also alters the flow path of the coolant fluid, and thus allows an expanded heat exchange area between the coolant fluid and the liquid-cooling heat sink 10, resulting in more efficient heat exchange between the coolant fluid and the liquid-cooling heat sink 10 and an additionally reduced temperature of the heat source.

Therefore, in the liquid-cooling heat sink according to the above embodiments, the blocking by the separator causes the coolant fluid to converge and exit after passing through the first and second heat sinking fins. Therefore, arranging the separator between the first and second heat sinking fins not only enhances the overall structural strength of the liquid-cooling heat sink, but also alters the flow path of the coolant fluid and thus allows an expanded heat exchange area between the coolant fluid and the liquid-cooling heat sink. This results in improved heat exchange efficiency between the coolant fluid and the liquid-cooling heat sink and an additionally reduced temperature of the heat source.

Further, the pluralities of first and second assembly holes in the fixation member differ at least partially in terms of position and are configured for assembly with two different objects, such as platforms associated with Intel and AMD CPUs. This allows the single liquid-cooling heat sink to be applicable to multiple platforms and thus suitable to be produced in an increased quantity at lower cost.

Although the present invention has been disclosed hereinabove by referencing a few embodiments, these embodiments are not intended to limit the present invention in any sense, and various changes and modifications may be made by those of ordinary skill in the art without departing from the spirit and scope of the present invention. Thus, the true scope of the invention is defined by the appended claims.

What is claimed is:

1. A liquid-cooling heat sink, comprising:
a substrate comprising a plate, a set of first heat sinking fins and a set of second heat sinking fins, the set of first heat sinking fins and the set of second heat sinking fins projecting from a same side of the plate;
a cover having a water inlet port and a water outlet port, the cover superimposed on the plate, the cover and the plate together delimiting a heat exchange chamber in which both the set of first heat sinking fins and the set of second heat sinking fins are confined; and
a separator disposed between the set of first heat sinking fins and the set of second heat sinking fins so as to divide the heat exchange chamber into a water inlet compartment and a water outlet compartment, the water inlet compartment in communication with the water inlet port, the water outlet compartment in communication with the water outlet port, the set of first heat sinking fins housed in the water inlet compartment, the set of second heat sinking fins housed in the water outlet compartment.

2. The liquid-cooling heat sink of claim 1, wherein a first side of the set of first heat sinking fins, a first side of the set of second heat sinking fins and a first side of the separator delimit a first communication channel together with the cover, the first communication channel communicatively connecting the water inlet compartment to the water outlet compartment.

3. The liquid-cooling heat sink of claim 2, wherein the set of first heat sinking fins comprises two subsets of first heat sinking fins, which are spaced apart from each other and define a water inlet passage between the two subsets of first heat sinking fins, the first communication channel communicatively connecting the water inlet passage to the water outlet compartment.

4. The liquid-cooling heat sink of claim 3, wherein the set of second heat sinking fins comprises two subsets of second heat sinking fins, which are spaced apart from each other and define a water outlet passage between the two subsets of second heat sinking fins, the first communication channel communicatively connecting the water inlet passage to the water outlet passage.

5. The liquid-cooling heat sink of claim 1, wherein a second side of the set of first heat sinking fins, a second side of the set of second heat sinking fins and a second side of the separator delimit a second communication channel together with the cover, the second communication channel communicatively connecting the water inlet compartment to the water outlet compartment.

6. The liquid-cooling heat sink of claim 1, wherein the separator is integrated with the cover on one side and engaged with the plate on the other side.

7. The liquid-cooling heat sink of claim 1, wherein the separator is engaged on opposing sides respectively with the plate and the cover.

8. The liquid-cooling heat sink of claim 1, wherein the set of first heat sinking fins and the set of second heat sinking fins are formed by skiving.

9. The liquid-cooling heat sink of claim 1, further comprising a fixation member assembled with the plate of the substrate, the fixation member comprising a plurality of assembly features configured to be assembled with another object by a fastener.

10. The liquid-cooling heat sink of claim 9, wherein the plurality of assembly features includes a plurality of first assembly holes and a plurality of second assembly holes, which are different from each other at least partially in terms of position and configured for assembly with two different objects.
